(19) United States
(12) Patent Application Publication
(10) Pub. No.: US 2020/0295299 A1
(43) Pub. Date: Sep. 17, 2020

(54) ORGANIC LIGHT-EMITTING DIODE THIN FILM ENCAPSULATION STRUCTURE

(71) Applicant: Wuhan China Star Optoelectronics Semiconductor Display Technologies Co., Ltd., Wuhan (CN)

(72) Inventors: Xuebing YIN, Wuhan (CN); Jun CAO, Wuhan (CN)

(21) Appl. No.: 16/484,136

(22) PCT Filed: Mar. 15, 2019
(86) PCT No.: PCT/CN2019/078298

§ 371 Date: Aug. 7, 2019

(30) Foreign Application Priority Data
Oct. 17, 2018 (CN) 201811208439.8

(51) Int. Cl. H01L 51/52

(52) U.S. Cl. CPC H01L 51/5253

(57) ABSTRACT

The present invention discloses an OLED thin film encapsulation structure, which includes a substrate, an insulating layer, a display layer, and a thin film encapsulation layer. A first trench is disposed in the insulating layer, the display layer is enclosed by the trench, and the thin film encapsulation layer includes a first inorganic layer and a first organic layer, wherein the first inorganic layer is in contact with the insulating layer at a position corresponding to the first trench, and has a thickness smaller than a depth of the first trench, such that a remaining depth of the first trench not covered by the first inorganic layer limits a boundary of the first organic layer. As such, the first inorganic layer of the thin film encapsulation structure can be directly in contact with the inorganic layer in the OLED structure, and a lateral intrusion path of water-oxygen can be prolonged.

### BACKGROUND OF INVENTION

### Field of Invention

The present invention relates to an encapsulation structure of an organic light-emitting diode (OLED), in particular to an (OLED) thin film encapsulation structure.

### Description of Prior Art

Organic light-emitting diodes (OLEDs) have been widely used due to its advantages of good self-luminous properties, superior contrast, fast response times, and flexible display.

Luminescent materials in the OLEDs are usually polymers or organic small molecules, and cathode materials are usually reactive metals having a low work function, such as magnesium, aluminum, and the like. Because these luminescent materials and cathode materials are very sensitive to water vapor and oxygen, water/oxygen permeation will greatly reduce lifespans of the OLEDs. In order to meet requirements of commercialization for the service life and stability of the OLEDs, the OLEDs have a very high requirement for the packaging effect. Therefore, packaging is very important in OLED production and is one of the key factors affecting the product yield.

Traditional OLED packaging technologies include: (1) Cover plate packaging technologies: coating a UV-curable sealant on an encapsulation glass/metal, or coating a sealant and filling a desiccant, and the sealant is cured to provide OLEDs with a relative sealed environment to isolate water and oxygen from entering; (2) Laser packaging technologies: coating glass glue on the encapsulation glass, volatilizing the solvent to become glass powder, after pairing an OLED substrate and an encapsulation cover plate, using laser to melt the glass powder to achieve bonding. The above conventional packaging technologies can achieve an effective water/oxygen barrier effect, but they will increase thicknesses and weights of devices, and thus is disadvantageous for preparing a flexible OLED.

In recent years, thin film packaging technologies have emerged to overcome the drawbacks of the traditional packaging technologies. They do not need to use the encapsulation cover and the sealant to encapsulate the OLED. Instead, the thin film encapsulation is used instead of the traditional glass encapsulation to realize the package of a large-size OLED, making the OLED thin and light. The so-called thin film encapsulation is to form inorganic-organic alternating layers on a surface of the OLED, that is, by depositing thin films to block water and oxygen, wherein the inorganic layers (having main components of silicon oxide, silicon nitride, and/or the like) are effective barriers for water/oxygen. However, in processes of preparing the inorganic layers, some pinholes or foreign matter defects are generated, and the organic layers (having main components of polymers, resin materials, and/or the like.) function to cover the defects of the inorganic layers, achieve planarization, and release stress between the inorganic layers, thus achieving the flexible package. The organic layers are mainly formed by inkjet printing (IJP).

Since contact surface characteristics of the organic layers and the inorganic layers are inconsistent, when the organic layers are ink-jet-coated, uneven diffusion of the ink, irregular edges, and ink flowing may occur on surfaces of the inorganic layers. In the prior art, multiple retaining walls are usually used to prevent ink from overflowing.

Referring to FIG. 9, a conventional organic light-emitting diode (OLED) thin film encapsulation structure is illustrated, which includes a substrate 910, an organic light-emitting diode (OLED) layer 920 disposed on the substrate 910, a retaining wall structure 940 having three levels of height that vary progressively disposed on the OLED layer 920, a thin film encapsulating layer 930 disposed on the substrate 910 and the retaining wall structure 940 and covering the retaining wall structure 940.

The retaining wall structure 940 is usually made of an organic material, and this structure of the organic material is easy to form a path of water vapor for lateral intrusion. In addition, because the adhesion between the organic material and the inorganic material is poor by its nature, peeling of a first inorganic layer in the retaining wall structure 940 and the thin film encapsulating layer 930 occurs, creating a risk of package failure.

Therefore, it is necessary to develop a novel type of an OLED thin film encapsulation structure to overcome the drawbacks of the prior art.

### SUMMARY OF INVENTION

An object of the present invention is to provide an organic light-emitting diode (OLED) thin film encapsulation structure to solve the problems of ink overflow, water and oxygen intrusion, and package failure caused by organic/inorganic layer peeling existing in the prior art.

In order to achieve the above object, the present invention provides an organic light-emitting diode (OLED) thin film encapsulation structure comprising: a substrate, an insulating layer, a display layer and a thin film encapsulation layer, wherein a first trench is disposed in the insulating layer, the display layer is enclosed by the trench, and the thin film encapsulation layer comprises a first inorganic layer and a first organic layer, wherein the first inorganic layer is in contact with the insulating layer at a position corresponding to the first trench, and has a thickness smaller than a depth of the first trench, such that a remaining depth of the first trench not covered by the first inorganic layer limits a boundary of the first organic layer.

Further, in other embodiments, the insulating layer comprises a gate insulating layer and a passivation insulating layer, and the first trench is down provided in the passivation insulating layer. In other embodiments, a bottom of the trench may be in contact with a surface of the gate insulating layer, that is, the first trench may block and break the passivation insulating layer; or may not be in contact with the surface of the gate insulating layer, but being located within the passivation insulating layer. The specifics may be determined as needed, and are not particularly limited.

Further, in other embodiments, the insulating layer comprises a gate insulating layer and a passivation insulating layer, and the first trench is down provided in the passivation insulating layer through the passivation insulating layer. In other embodiments, a bottom of the trench may be in contact with a surface of the substrate, that is, the first trench may block and break the passivation insulating layer and the gate insulating layer; or may not be in contact with the surface of the substrate, but being located within the passivation insulating layer. The specifics may be determined as needed, and are not particularly limited.

Further, in other embodiments, the first trench has a width ranging from 10 to 100 μm.

Further, in other embodiments, the first trench has the depth ranging from 0.5 to 2 μm.

Further, in other embodiments, the first trench is composed of a plurality of independent grooves which cooperate with each other to surround the display layer therein. Shapes of the independent grooves may be various, such as L-shaped grooves, U-shaped grooves, or arc grooves, as long as that the independent grooves are mated together end to end to form a substantially closed integral groove structure, to surround the display layer therein.

Further, in other embodiments, the thin film encapsulation layer further comprises a second inorganic layer covering the first organic layer and completely covering the first trench.

Further, in other embodiments, a second trench is further disposed in the insulating layer, and the first trench is enclosed in the second trench.

Further, in other embodiments, material of the insulating layer may be silicon nitride, silicon oxide, or silicon oxynitride. The specifics may be determined as needed, and are not particularly limited.

Further, in other embodiments, the display layer comprises a planarization layer, a pixel definition layer, and an organic light-emitting diode (OLED) layer, wherein the planarization layer is disposed on a surface of the passivation insulating layer, the pixel definition layer is disposed on a surface of the planarization layer, and the OLED layer is disposed on a surface of the pixel definition layer.

Compared with the prior art, the present invention has the beneficial effects that the present invention provides an organic light-emitting diode (OLED) thin film encapsulation structure, which adopts a whole new trench instead of the existing retaining wall structure, so that the first inorganic layer of the thin film encapsulation structure can be directly in contact with the inorganic layer in the OLED structure, prolonging a lateral intrusion path of water-oxygen, while eliminating a risk of package failure caused by peeling of the inorganic/organic thin film layer in the prior art due to the direct contact between two inorganic layers.

Further, because the trench structure has a certain depth, it is not completely covered by the first inorganic layer of the thin film encapsulation structure, and the remaining uncovered portion can serve to define a boundary of the first organic layer in the thin film encapsulation structure, thus solving the problem of ink overflow.

### BRIEF DESCRIPTION OF DRAWINGS

FIG. 1 is a cross-sectional view showing an encapsulation structure of an organic light-emitting diode (OLED) thin film according to Embodiment 1 of the present invention.

FIG. 2 is a schematic top view of an OLED thin film encapsulation structure according to Embodiment 1 of the present invention;

FIG. 3 is a cross-sectional view showing an encapsulation structure of an OLED thin film according to Embodiment 2 of the present invention.

FIG. 4 is a cross-sectional view showing an encapsulation structure of an OLED thin film according to Embodiment 3 of the present invention.

FIG. 5 is a schematic top view of an OLED thin film encapsulation structure according to Embodiment 3 of the present invention;

FIG. 6 is a cross-sectional view showing an encapsulation structure of an OLED thin film according to Embodiment 4 of the present invention.

FIG. 7 is schematic top view showing an OLED thin film encapsulation structure according to Embodiment 5 of the present invention.

FIG. 8 is schematic top view showing an OLED thin film encapsulation structure according to Embodiment 6 of the present invention.

FIG. 9 is a cross-sectional view showing a conventional OLED thin film encapsulation structure.

### DETAILED DESCRIPTION OF PREFERRED EMBODIMENTS

Please refer to the figures in the drawings, in which, like numbers refer to like elements throughout the description of the figures. Hereinafter, the present invention will be described in further detail with reference to examples. It is to be understood, however, that these examples are for illustrative purposes only and are not intended to limit the scope of the present invention.

The following disclosure provides many different embodiments, or examples, for implementing different features of the present invention. Specific examples of components and arrangements are described below to simplify the present disclosure. These are, of course, merely examples and are not intended to limit the present invention.

In the description of the present invention, it is to be understood that the terms “center”, “lateral”, “upper”, “lower”, “left”, “right”, “vertical”, “horizontal”, “top”, “bottom”, “inside”, “outside” and the like are based on the orientation or positional relationship shown in the drawings, and is merely for the convenience of describing the present invention and simplifying the description, and does not indicate or imply that the indicated devices or components must to be in particular orientations, or constructed and operated in a particular orientation, and thus are not to be construed as limiting The present invention. Furthermore, the terms “first”, “second”, etc. in the specification and claims of the present invention and the above figures are used to distinguish similar objects, and are not necessarily used to describe a specific order or prioritization. It should be understood that the objects so described are interchangeable when it is appropriate. Moreover, the terms “including” and “having” and any variations thereof are intended to cover a non-exclusive “inclusion”.

In the description of the present invention, it should be noted that the terms “installation”, “connection”, and “bonding” are to be understood broadly unless otherwise explicitly defined and limited. For example, it may be fixed connection, detachable connection, or integrally connection; being mechanical or electrical connection; also, being directly connection, indirectly connection through an intermediate medium, or internal communication of two components. The specific meaning of the above terms in the present invention can be understood in a specific case by those skilled in the art.

The terminology used herein is for the purpose of describing particular embodiments only and is not intended to be limiting of exemplary embodiments. The singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, components and/or groups thereof, but do not preclude the presence or addition of one or more other features, integers, steps, operations, elements, components and/or groups thereof.

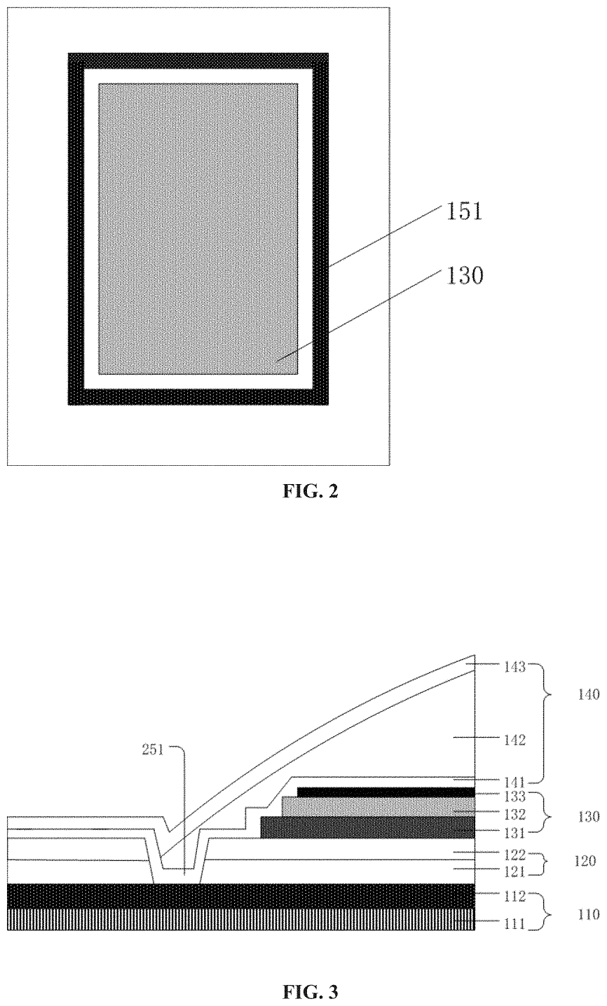

Referring to FIG. 2 and FIG. 3, the present invention provides an organic light-emitting diode (OLED) encapsulation structure including a substrate 110, an insulating layer 120, a display layer 130, and a thin film encapsulation layer 140.

The substrate 110 includes a flexible substrate 111 and a buffer layer 112 disposed on a surface of the flexible substrate 111. The flexible substrate 111 is a polyimide thin film serving as a substrate of a flexible display panel. The polyimide thin film is the most excellent thin film-based insulating material in the world, having a strong tensile strength, and made by polycondensation and film-casting of pyromellitic dianhydride and diaminodiphenyl ether in a strong polar solvent, followed by imidization.

The insulating layer 120 includes a gate insulating layer 121 and a passivation insulating layer 122. The gate insulating layer 121 is disposed on a surface of the buffer layer 112. The passivation insulating layer 122 is disposed on a surface of the gate insulating layer 121 and completely covers the gate insulating layer 121. In the present embodiment, material of the gate insulating layer 121 and the passivation insulating layer 122 is silicon nitride, silicon oxide, silicon oxynitride or the like.

The display layer 130 includes a planarization layer 131, a pixel definition layer 132, and an OLED layer 133. The planarization layer 131 is disposed on a surface of the passivation insulating layer 122, the pixel defining layer 132 is disposed on a surface of the planarization layer 131, and the OLED layer 133 is disposed on a surface of the pixel defining layer 132. The planarization layer 131 and the pixel definition layer 132 are made of a transparent organic material, having good elasticity and flexibility, being able to flatten and buffer stress of the layer.

The thin film encapsulation layer 140 includes a first inorganic layer 141, a first organic layer 142, and a second inorganic layer 143. A first trench 151 is disposed on the insulating layer 120 and the display layer 130 is enclosed by the trench. The first inorganic layer 141 is in contact with the insulating layer 120 at a position corresponding to the first trench 151. A thickness of the first inorganic layer 141 is smaller than a depth of the first trench 151, such that a remaining depth of the first trench 151 not covered by the first inorganic layer 141 is used to deposit the first organic layer 142. This arrangement limits a boundary of the first organic layer, thereby solving the problem of ink overflow.

The second inorganic layer 143 covers the first organic layer 142 and completely covering the first trench 151.

Specifically, the first trench 151 is disposed in the passivation insulating layer 122, and a bottom thereof is in contact with the surface of the gate insulating layer 121, that is, to block and break the passivation insulating layer 122. In other embodiments, the bottom of the first trench 151 may also not be in contact with the surface of the gate insulating layer 121, but only in the passivation insulating layer 122. The specifics may be determined as needed, and are not particularly limited.

The first trench 151 has a width ranging from 10 to 100 μm and a depth ranging from 0.5 to 2 μm.

### Embodiment 1

Referring to FIG. 2 and FIG. 3, the present invention provides an OLED encapsulation structure including a substrate 110, an insulating layer 120, a display layer 130, and a thin film encapsulation layer 140.

The substrate 110 includes a flexible substrate 111 and a buffer layer 112 disposed on a surface of the flexible substrate 111. The flexible substrate 111 is a polyimide thin film serving as a substrate of a flexible display panel. The polyimide thin film is the most excellent thin film-based insulating material in the world, having a strong tensile strength, and made by polycondensation and film-casting of pyromellitic dianhydride and diaminodiphenyl ether in a strong polar solvent, followed by imidization.

The insulating layer 120 includes a gate insulating layer 121 and a passivation insulating layer 122. The gate insulating layer 121 is disposed on a surface of the buffer layer 112. The passivation insulating layer 122 is disposed on a surface of the gate insulating layer 121 and completely covers the gate insulating layer 121. In this embodiment, material of the gate insulating layer 121 and the passivation insulating layer 122 is silicon nitride, silicon oxide, silicon oxynitride or the like.

The display layer 130 includes a planarization layer 131, a pixel definition layer 132, and an OLED layer 133. The planarization layer 131 is disposed on a surface of the passivation insulating layer 122, the pixel defining layer 132 is disposed on a surface of the planarization layer 131, and the OLED layer 133 is disposed on a surface of the pixel defining layer 132. The planarization layer 131 and the pixel definition layer 132 are made of a transparent organic material, having good elasticity and flexibility, being able to flatten and buffer stress of the layer.

The thin film encapsulation layer 140 includes a first inorganic layer 141, a first organic layer 142, and a second inorganic layer 143. A first trench 151 is disposed on the insulating layer 120 and the display layer 130 is enclosed by the trench. The first inorganic layer 141 is in contact with the insulating layer 120 at a position corresponding to the first trench 151. A thickness of the first inorganic layer 141 is smaller than a depth of the first trench 151, such that a remaining depth of the first trench 151 not covered by the first inorganic layer 141 is used to deposit the first organic layer 142. This arrangement limits a boundary of the first organic layer, thereby solving the problem of ink overflow.

The second inorganic layer 143 covers the first organic layer 142 and completely covering the first trench 151.

Specifically, the first trench 151 is disposed in the passivation insulating layer 122, and a bottom thereof is in contact with the surface of the gate insulating layer 121, that is, to block and break the passivation insulating layer 122. In other embodiments, the bottom of the first trench 151 may also not be in contact with the surface of the gate insulating layer 121, but only in the passivation insulating layer 122. The specifics may be determined as needed, and are not particularly limited.

The first trench 151 has a width ranging from 10 to 100 μm and a depth ranging from 0.5 to 2 μm.

### Embodiment 2

Referring to FIG. 3, the OLED thin film encapsulation structure in this embodiment is substantially the same as that in Embodiment 1. The same structure can be referred to the above, and details are not repeated herein for brevity. A main difference is that the first trench 251 is disposed in the gate insulating layer 121 through the passivation insulating layer 122, and a bottom of the first trench 251 is in contact with a surface of the substrate 110, that is, the first trench 251 blocks and breaks the passivation insulating layer 132 and the gate insulating layer 131. In other embodiments, the bottom of the first trench 251 may also not be in contact with the surface of the substrate 110, but only in the gate insulating layer 121. The specifics may be determined as needed, and are not particularly limited.

### Embodiment 3

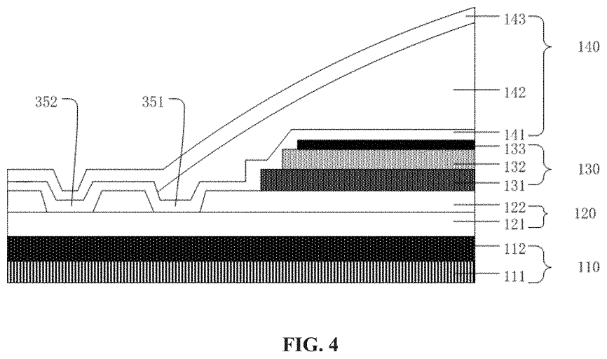

Referring to FIG. 4 and FIG. 5, the OLED thin film encapsulation structure in this embodiment is substantially the same as that in Embodiment 1. The same structure can be referred to the above, and details are not repeated herein for brevity. A main difference is that a second groove 352 is also provided in the passivation insulating layer 122, to enclose a first trench 351 therein. Such an arrangement prolongs a lateral intrusion path of water-oxygen. Bottoms of the first trench 351 and the second trench 352 are in contact with a surface of the gate insulating layer 121, that is, the first trench 351 and the second trench 352 block and break the passivation insulating layer 122. In other embodiments, the bottoms of the first trench 351 and the second trench 352 may also not be in contact with the surface of the gate insulating layer 121, but only in the passivation insulating layer 122. The specifics may be determined as needed, and are not particularly limited.

### Embodiment 4

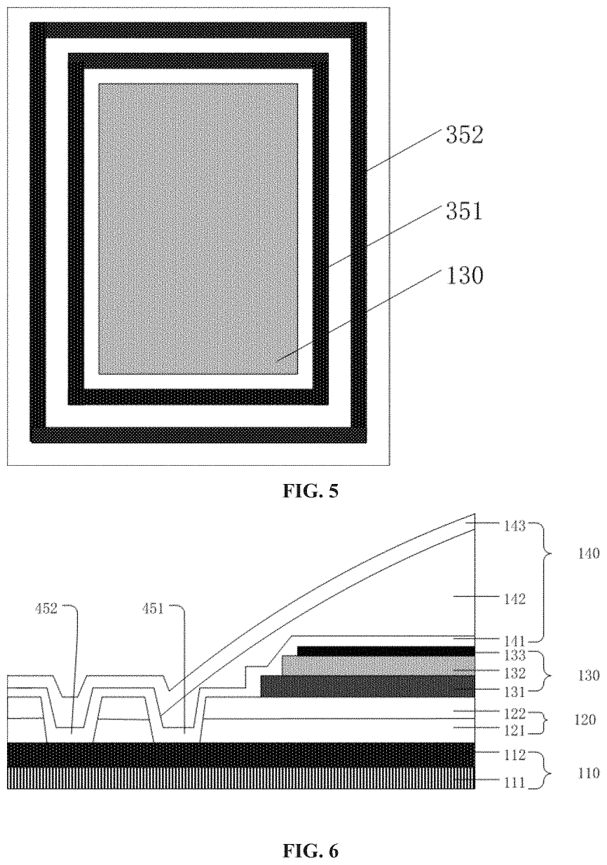

Referring to FIG. 6, the OLED thin film encapsulation structure in this embodiment is substantially the same as that in Embodiment 2. The same structure can be referred to the above, and details are not repeated herein for brevity. A main difference is that a second trench 452 is also disposed in the gate insulating layer 121, to enclose a first groove 451 therein. Bottoms of the first trench 451 and the second trench 452 are in contact with the surface of the substrate 110, that is, the first trench 451 and the second trench 452 block and break the gate insulating layer 121 and the passivation insulating layer 122. In other embodiments, the bottoms of the first trench 451 and the second trench 452 may also not be in contact with the surface of the substrate 110, but only in the gate insulating layer 121. The specifics may be determined as needed, and are not particularly limited.

### Embodiment 5

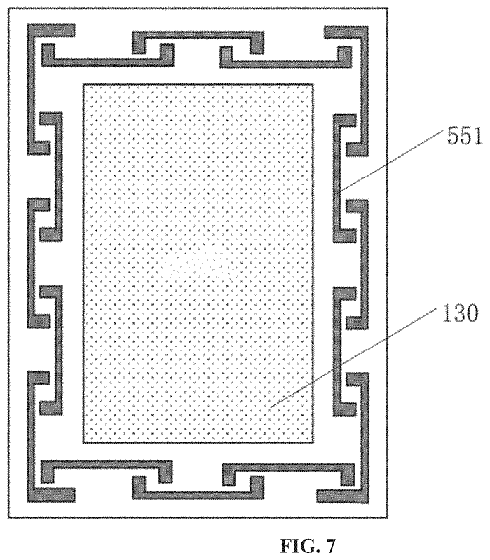

Referring to FIG. 7, the OLED thin film encapsulation structure in this embodiment is substantially the same as that in Embodiment 1. The same structure can be referred to the above, and details are not described herein. A main difference is that the first trench is composed of a multiple independent groove structure. These independent grooves are U-shaped grooves 551.

### Embodiment 6

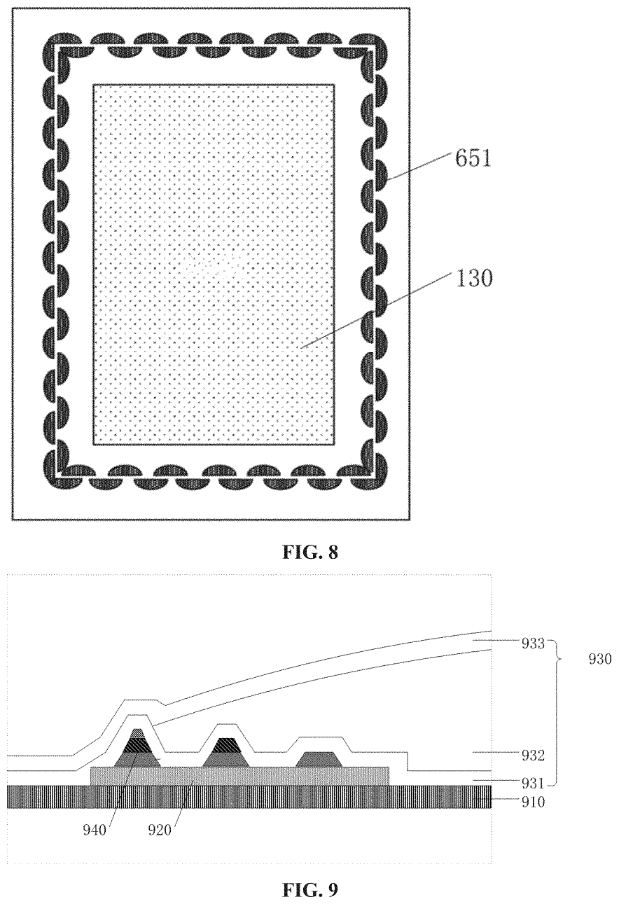

Referring to FIG. 8, the OLED thin film encapsulation structure in the embodiment is substantially the same as that in Embodiment 1. The same structure can be referred to the above, and details are not repeated herein for brevity. A main difference is that the first trench is composed of a plurality of independent grooves, and these independent grooves are arc-shaped grooves 651.

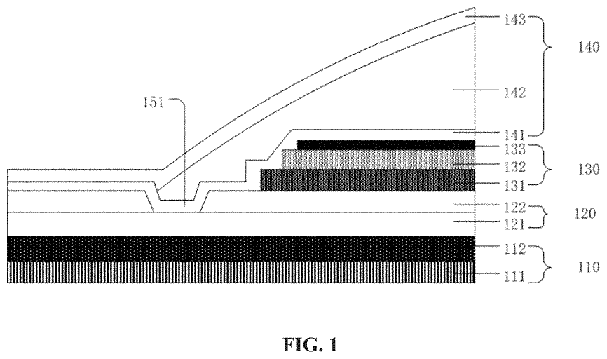

The shape of the first groove is not limited to the shapes shown in FIG. 1 to FIG. 8, and may be other continuous or non-continuously overlapping heterostructures, as long as that the independent grooves are mated together end to end to form a substantially closed integral groove structure to surround the display layer 130 therein.

While the present invention has been described by way of example and in terms of the preferred embodiments, it is to be understood that the present invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. An organic light-emitting diode (OLED) thin film encapsulation structure, comprising a substrate, an insulating layer, a display layer, and a thin film encapsulation layer, wherein a first trench is disposed in the insulating layer, the display layer is enclosed by the trench, and the thin film encapsulation layer comprises a first inorganic layer and a first organic layer, wherein the first inorganic layer is in contact with the insulating layer at a position corresponding to the first trench, and has a thickness smaller than a depth of the first trench, such that a remaining depth of the first trench not covered by the first inorganic layer limits a boundary of the first organic layer.

2. The OLED thin film encapsulation structure according to claim 1, wherein the insulating layer comprises a gate insulating layer and a passivation insulating layer, and the first trench is provided in the passivation insulating layer.

3. The OLED thin film encapsulation structure according to claim 2, wherein the first trench is provided in the gate insulating layer through the passivation insulating layer.

4. The OLED thin film encapsulation structure according to claim 1, wherein the first trench has a width ranging from 10 to 100 μm.

5. The OLED thin film encapsulation structure according to claim 1, wherein the first trench has the depth ranging from 0.5 to 2 μm.

6. The OLED thin film encapsulation structure according to claim 1, wherein the first trench is composed of a plurality of independent grooves, and shapes of the independent grooves are L-shaped grooves, U-shaped grooves, or arc grooves.

7. The OLED thin film encapsulation structure according to claim 1, wherein the thin film encapsulation layer further comprises a second inorganic layer covering the first organic layer and completely covering the first trench.

8. The OLED thin film encapsulation structure according to claim 1, wherein a second trench is further disposed in the insulating layer, and the first trench is enclosed in the second trench.

9. The OLED thin film encapsulation structure according to claim 1, wherein material of the insulating layer is silicon nitride.

10. The OLED thin film encapsulation structure according to claim 1, wherein the display layer comprises a planarization layer, a pixel definition layer, and an organic light-emitting diode (OLED) layer, wherein the planarization layer is disposed on a surface of the passivation insulating layer, the pixel definition layer is disposed on a surface of the planarization layer, and the OLED layer is disposed on a surface of the pixel definition layer.
